(19) United States
(12) Patent Application Publication
(10) Pub. No.: US 2021/0098987 A1
(43) Pub. Date: Apr. 1, 2021

(54) ELECTROSTATIC DISCHARGE PROTECTION FOR STACKED-DIE SYSTEM

(71) Applicants: Priya Walimbe, Folsom, CA (US); Steven S. Poon, Sunnyvale, CA (US); Marco Escalante, Hillsboro, OR (US); Abhishek Sharma, Noida (IN)

(72) Inventors: Priya Walimbe, Folsom, CA (US); Steven S. Poon, Sunnyvale, CA (US); Marco Escalante, Hillsboro, OR (US); Abhishek Sharma, Noida (IN)

(21) Appl. No.: 16/584,251

(22) Filed: Sep. 26, 2019

(51) Int. Cl. H02H 9/04; H01L 25/065; H01L 27/02; H01L 23/00; H01L 25/18; H01L 23/66; H01L 23/14; G06F 17/50

(52) U.S. Cl. CPC H02H 9/046; H01L 2223/6616; H01L 27/0255; H01L 24/16; H01L 24/17; H01L 25/18; H01L 24/48; H01L 23/66; H01L 23/145; G06F 17/5009; G06F 17/5045; H01L 24/73; H01L 2224/16145; H01L 2224/16225; H01L 2225/06541; H01L 2924/1432; H01L 2924/1434; H01L 2223/6677; H01L 2224/17181; H01L 2224/48091; H01L 2224/48106; H01L 2224/48225; H01L 2224/73257; H01L 2225/0651; H01L 2225/06513; H01L 2225/06517; H01L 2223/6611; H01L 25/0657

(57) ABSTRACT

Some embodiments include apparatuses and methods using a conductive connection, a first die, and a second die arranged in a stack with the first die. The first die includes a first electrode static discharge (ESD) protection structure, which includes a first number circuit elements coupled to the conductive connection. The second die includes a second ESD protection structure, which includes a second number of circuit elements coupled to the first number of circuit elements. The first number of circuit elements and the second number of circuit elements are based on a combined model of the first and second ESD protection structures.

### TECHNICAL FIELD

Embodiments described herein pertain to semiconductor devices and systems. Some embodiments relate to electrostatic discharge (ESD) protection of such devices and systems.

### BACKGROUND

Semiconductor devices or systems often have circuitry formed in or on a semiconductor die. The die usually has an ESD protection structure (e.g., ESD diodes and associated ESD circuitry). The ESD protection structure can operate to protect other circuitry of the die from a relatively high voltage generated by an undesired ESD event. Such an ESD event may occur at a conductive connection (e.g., a pin or a conductive contact) on a circuit path of the die. Many conventional ESD solutions are available for designing ESD protection structures. However, such conventional ESD solutions normally lack techniques to deal with devices or systems that have multiple dies arranged in a certain way.

### BRIEF DESCRIPTION OF THE DRAWINGS

FIG. 1 shows an example system including a package having dies arranged in a stack, according to some embodiments described herein.

FIG. 2 shows a schematic diagram of a portion of the package of FIG. 1 including an ESD protection structure located in the dies of the package, according to some embodiments described herein.

FIG. 3 shows a combined simulation model for the ESD protection structure of the dies of the package of FIG. 2, according to some embodiments described herein.

FIG. 4 shows a combined simulation file based on the combined simulation model of FIG. 3, according to some embodiments described herein.

FIG. 5 is a flowchart showing a method for an ESD solution for the package of FIG. 1 and FIG. 2, according to some embodiments described herein,

FIG. 6 shows a schematic diagram of a diode circuit of the ESD protection structure of the package of FIG. 1 and FIG. 2, according to some embodiments described herein.

FIG. 7 shows an apparatus in the form of a system (e.g., electronic system), according to some embodiments described herein.

### DETAILED DESCRIPTION

The techniques described herein relate to a novel ESD solution for an electronic package that include multiple dies. The dies can be formed from the same technology node or different technologies nodes. The dies can be arranged one over another in a stack that is part of a stacked-die structure of the package. The techniques described herein allow the ESD solution to be distributed between the dies of the package to provide an optimized ESD solution for each of the dies.

In some examples, the described techniques include generating simulation models (e.g., circuit diagram model) for the ESD protection structure for the dies, generating a combined simulation file (e.g., simulation description) based on the simulation models, and executing (e.g., co-simulating) the combined simulation file to generate a simulation result. The described techniques can also include configuring (e.g., programming) circuit elements (e.g., ESD diode circuits) of the ESD protection structure of each of the dies based on the simulation result to achieve optimal ESD protection in each of the dies of the package. Improvements and benefits of the described techniques are discussed below.

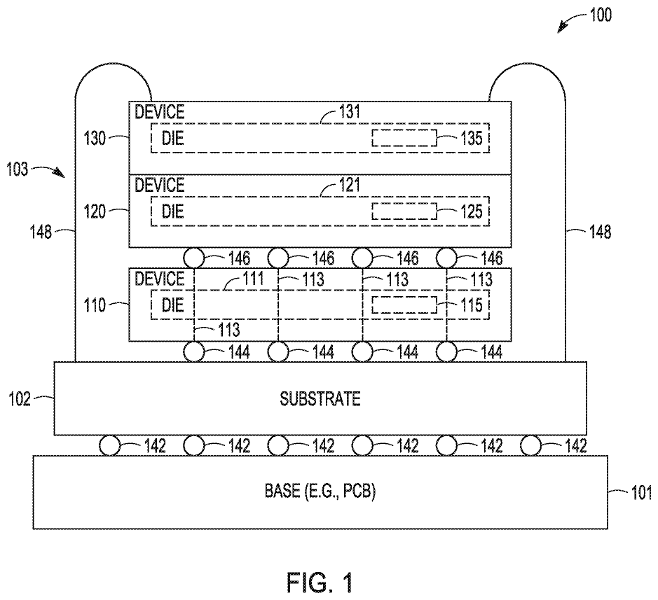

FIG. 1 shows an example an apparatus 100 including devices 110, 120, and 130 arranged in a stack, according to some embodiments described herein. Apparatus 100 can include or be included (e.g., can be a part of) a system (e.g., electronic system). Such a system can include or be included in a cellphone, a tablet, a computer, a system-on-chip (SoC), system on package (SoP), or other types of electronic systems.

As shown in FIG. 1, apparatus 100 can include a base 101, a substrate 102 over base 101, and devices 110, 120, and 130 stacked one over another over substrate 102. Apparatus 100 can also include connections (e.g., interconnect structures to establish electrical connections) 142, 144, 146, and 148 to provide electrical and physical interconnection between components (e.g., base 101, substrate 102, and devices 110, 120, and 130) of apparatus 100. For simplicity, FIG. 1 shows a specific number (quantity) of each of connections 142, 144, 146, and 148 as an example. However, the number of each of connections 142, 144, 146, and 148 can vary.

Base 101 of apparatus 100 in FIG. 1 can include a printed circuit board (PCB). Substrate 102 can be an organic substrate and can include conductive paths (e.g., signal paths and power paths, not shown) that are electrically coupled between connections 142 and 144.

Each of devices 110, 120, and 130 can include a die (e.g., a semiconductor die), such as die 111, 121, or 131. Each of dies 111, 121, and 131 can include circuitry to perform a function (or multiple functions). For example, device 110 can be an active interface device, such that die 111 can include circuits, such as, for example, a cache memory circuit (e.g., static random-access memory circuit) 115, an input/out (I/O) control circuit, a communication circuit (e.g., internet control circuit), and other types circuits. Device 120 can be a control logic device (e.g., compute device), such that die 121 can include a logic circuitry unit, such as, for example, a processing unit 125 and other circuitry. Processing unit 125 can include a central processing unit (CPU), a graphics processing unit (GPU), a combination of a CPU and GPU, or other types of processing units. Device 130 can be a memory device, such that die 131 can include memory cells (e.g., dynamic random-access memory (DRAM) cells) 135 to store information. In an alternative structure of apparatus 100, device 120 can include a memory device (e.g., a DRAM device).

In FIG. 1, each of connections 142, 144, 146, and 148 can include conductive material (e.g., metals and alloys) to carry electrical signals. For example, connections 142 can include solder balls (e.g., solder balls in a ball grid array (BGA) package) or other types of electrical connections. Connections 142 can provide electrical connections (through conductive paths (not shown) in substrate 102) between device 110 (or one more of devices 110, 120, and 130) and other devices (not shown) located on base 101.

Connections 144 can include a controlled collapse chip connection (C4) or other types of electrical connections. Connections 144 can include I/O connections (e.g., I/O pads, I/O nodes, or I/O terminals), supply power (e.g., supply voltage Vcc) connections, and ground (e.g., Vss) connections of device 110.

Connections 146 can include solder balls, solder bumps (e.g., conductive micro-bumps), or other types of electrical connections. Connections 146 can include I/O connections (e.g., I/O pads, I/O nodes, or I/O terminals), supply power (e.g., Vcc) connections, and ground (e.g., Vss) connections of device 120.

Connections 148 can include metal (e.g., copper) wires that can provide electrical connections between circuitry of device 130 and conductive paths of substrate 102. Alternatively, connections (e.g., wired connections) 148 can be omitted and device 130 can electrically communicate with one of more of device 110, 120, and substrate 102 through alternative connections (e.g., conductive paths) extending at least partially through device 120. For example, such alternative connections include conductive structures extending through a components structure (e.g., substrate, die, interposer, etc.), the conductive structures are commonly insulated from the surrounding structure. Such conductive structures are commonly generically termed in the art “through silicon vias” (TSVs), without requiring or implying that the surrounding structure is or includes silicon. Such conductive structures are sometimes alternatively referred to in the art as “through substrate vias,” again without requiring or implying that the surrounding structure is in fact a “substrate.” As a result, for purposes of the present disclosure, the two terms are equivalent to one another.

Substrate 102, devices 110, 120, and 130, and connections 142, 144, 146, and 148 can be part of (e.g., can be included in) a package 103. Examples of package 103 include SoC, SiP, or other types of electronic packages.

As shown in FIG. 1, device 110, 120, and 130 can be arranged (e.g., can be formed) one over another in a stack over substrate 102 (arranged in a direction perpendicular to substrate 102). In this stacked structure (e.g., stacked-die structure (stacked-die topology)), all or some (fewer than all) of the electrical paths from substrate 102 to device 120 can go through device 110. Device 110 can include conductive structures 113 (e.g., conductive TSVs that can be part of the electrical paths going through substrate 102, through device 110, and at least partially through device 120. For example, as shown in FIG. 1, each of conductive structures 113 (e.g., each of the TSVs) can include a first end coupled to substrate 102 through one of connections (e.g., C4 connections) 144, and a second end coupled to die 121 through one of connections (e.g., micro-bumps) 146.

Package 103 can include an ESD protection structure (ESD protection circuitry) in each of devices 110 and 120. For example, package 103 can include an ESD protection structure in die 111, and another ESD protection structure in die 121.

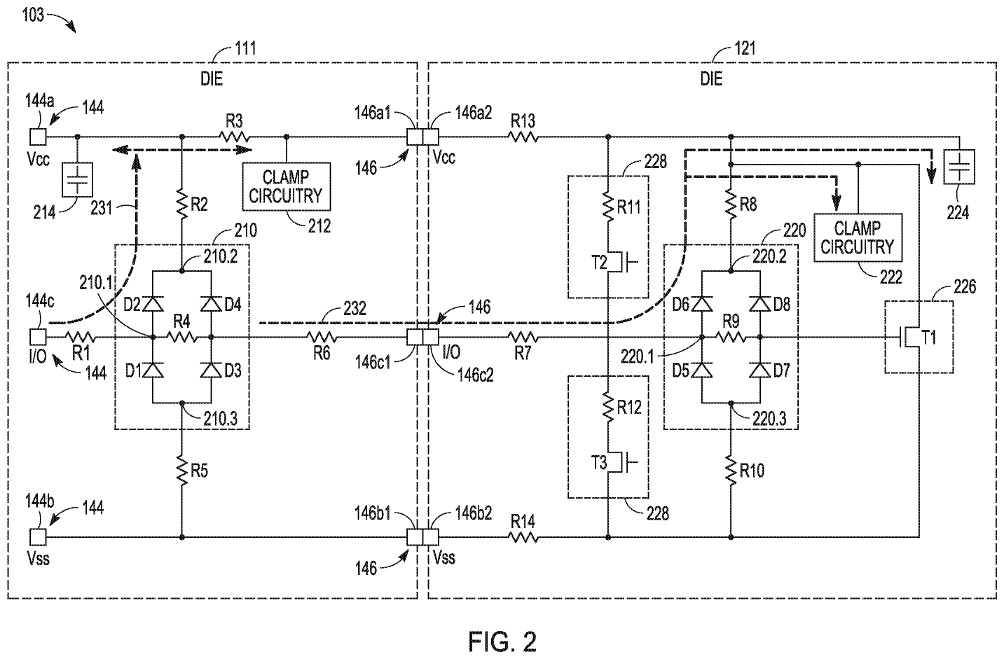

FIG. 2 shows a schematic diagram of a portion of package 103 of FIG. 1 including the ESD protection structure located in dies 111 and 121, according to some embodiments described herein. As shown in FIG. 2, die 111 can include diode circuitry 210, clamp circuitry 212, and capacitor circuitry 214. Die 121 can include diode circuitry 220, clamp circuitry 222, capacitor circuitry 224, a receiver circuit 226 (which can include a transistor T1), and a transmitter circuit 228 (which can include transistors T2 and T3). Die 111 may include a receiver circuit, a transmitter circuit, or both (not shown) coupled to diode circuitry 210 in ways similar to receiver and transmitter circuits 226 and 228, respectively (of die 121) coupled to diode circuitry 220. For simplicity and to help focus on the techniques described herein, circuitry of other portions of each of dies 111 and 121 is omitted from FIG. 2.

Diode circuitry 210 and clamp circuitry 212 can be part of an ESD protection structure (e.g., ESD protection circuitry) of die 111. As shown in FIG. 2, diode circuitry 210 can include diode circuits (e.g., ESD diode circuits) D1, D2, D3, and D4. Each of diode circuits D1 and D3 can be coupled between nodes 210.1 and 210.3. Each of diode circuits D2 and D4 can be coupled between nodes 210.1 and 210.2. In some structures of die 111, diode circuits D3 and D4 may be omitted.

Diode circuitry 220 and clamp circuitry 222 can be part of an ESD protection structure (e.g., ESD protection circuitry) of die 121. As shown in FIG. 2, diode circuitry 220 can include diode circuits D5, D6, D7, and D8. Each of diode circuits D5 and D7 can be coupled between nodes 220.1 and 220.3. Each of diode circuits D6 and D8 can be coupled between nodes 220.1 and 220.2. In some structures of die 121, diode circuits D7 and D8 may be omitted.

As shown in FIG. 2, package 103 can include resistors R1 through R14. Some of resistors R1 through R14 may not represent actual resistors of package 103, but they may represent path resistances of respective conductive paths between circuit elements of package 103. For example, resistor R4 (in die 111) and resistor R9 (in die 121) may represent actual resistors of package 103, and other resistors (e.g., resistors shown in FIG. 2 except for resistors R4 and R9) may represent respective path resistances between circuit elements of package 103.

As shown in FIG. 2, package 103 can include terminals 144a, 144b, 144c, 146a1, 146b1, 146c1, 146a2, 146b2, and 146c2 that can include conductive pads, conductive nodes, conductive contacts, or other types conductive structures.

Terminals 144a, 144b, and 144c (at die 111) can be part of respective connections (three different connections) 144 between die 111 and substrate 102 (FIG. 1). Each of terminals 146a1, 146b1, and 146cl (on die 111 side) can be part of a conductive structure (e.g., conductive (e.g., solder) contact or conductive pad) of die 111. Each of terminals 146a2, 146b2, and 146c2 (on die 121 side) can be part of a conductive structure (e.g., conductive (e.g., solder) contact or conductive pad) of die 121.

As shown in FIG. 2, terminals 146a1, 146b1, and 142c1 can be coupled to terminals 146a2, 146b2, and 146c2, respectively, and can be part of respective connections (three different connections) 146 between dies 111 and 121. For example, terminals 146al and 146a2 can be electrically coupled to each other (e.g., directly contact each other) to form part of one of connections 146 between dies 111 and 121. Terminals 146b1 and 146b2 can be electrically coupled to each other (e.g., directly contact each other) to form part of one of connections 146 between dies 111 and 121. Terminals 146c1 and 146c2 can be electrically coupled to each other (e.g., directly contact each other) to form part of one of connections 146 between dies 111 and 121.

Terminals 144a and 144b can include supply terminals (e.g., power and ground terminals (or nodes)) that can be configured to carry (e.g., to receive) power signal (e.g., supply voltage Vcc) and ground signal (e.g., ground voltage Vss), respectively. Terminal 144c can include an I/O terminal (e.g., I/O pad or I/O node) that can be configured to carry (e.g., transmit and receive) I/O signals (e.g., between die 111 and substrate 102 of FIG. 1). I/O signals can include non-power signals and non-ground signals (for example, data signals that are transmitted to or provided by die 111).

Terminals 146a1 and 146b1 can include supply terminals that can be configured to carry power and ground signals, respectively. Terminal 146c1 can include an I/O terminal (e.g., I/O pad or I/O node) that can be configured to carry I/O signals (e.g., data signals) between die 111 and die 121.

Terminals 146a2 and 146b2 can include supply terminals that can be configured to carry power and ground signals, respectively. Terminal 146c2 can include an I/O terminal (e.g., I/O node) that can be configured to I/O signals (e.g., data signals) between die 111 and die 121.

As shown in FIG. 2, package 103 can include paths 231 and 232. Paths 231 and 232 can represent ESD paths (or a combination of ESD paths) in package 103. Node 210.1 can be part of path 231. Node 220.1 can be part of path 232. Paths 231 and 232 can discharge a current caused by an ESD event that may occur (e.g., originate) at terminal 144c. For example, if an ESD event occurs at terminal 144c, an amount of current from the example ESD event may flow from terminal 144c through node 210.1 and through at least one of diode circuits D1, D2, D3, and D4 (e.g., through diode circuits D2 and D4) to at least one of terminal 144a, terminal 146a, clamp circuitry 212, and capacitor circuitry 214 in die 111. Another amount of current from the example ESD event may flow from node 210.1 (node between diode circuits D1 and D2) through at least one of diode circuits D5, D6, D7, and D8 (e.g., through diode circuits D6 and D8) to at least one of clamp circuitry 222 and capacitor circuitry 224.

Thus, in the stacked-die structure of package 103, current from the ESD event at terminal 144c may split (e.g., through paths 231 and 232) between die 111 and die 121. The ratio of such a current splitting can be difficult to determine because ESD path resistances between die 111 and die 121 can depend on relative ESD path resistances between dies 111 and 121.

A conventional monolithic ESD solution may be used in the stacked-die structure of package 103. However, the conventional monolithic ESD solution often lacks pre-defined ESD rules for a current splitting in a stacked-die structure (e.g., the structure of package 103). Thus, a conventional monolithic ESD solution may be used separately for each die of package 103. However, using such a conventional monolithic ESD solution separately for each die may result in an overdesign, affect (e.g., increase) I/O pad capacitance of package 103, impact I/O performance of package 103, and reduce I/O timing margins. It may also add extra pin leakage (e.g., current leakage) that could affect power consumption in package 103.

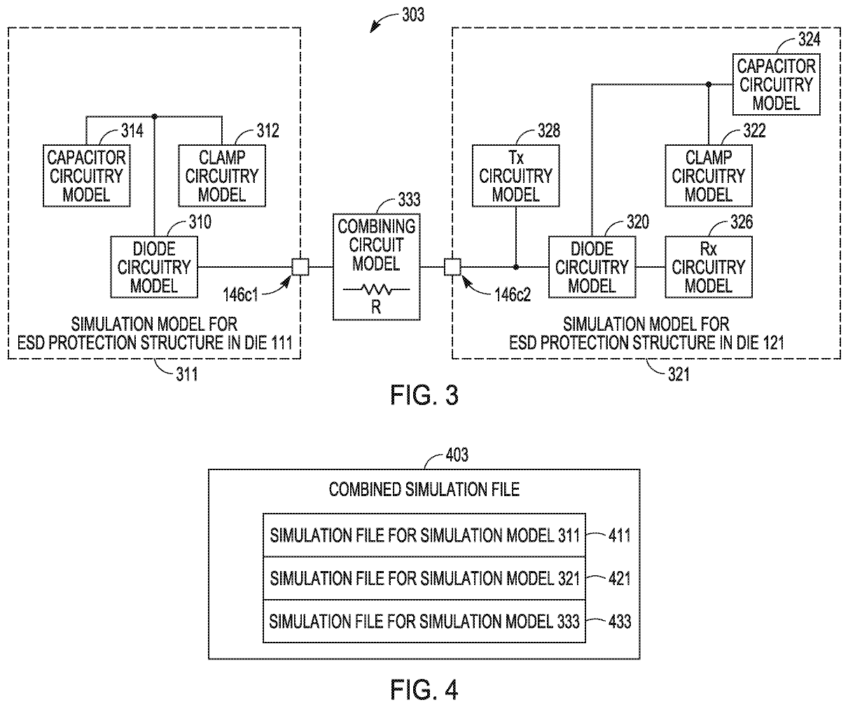

The techniques described herein provide an optimized ESD solution for each of dies 111 and 121 of package 103 and allow each of dies 111 and 121 to meet specifications related to performance (e.g., enable I/O performance at relatively high frequencies). The ESD solution described herein can allow I/O pad capacitance of package 103 to be relatively small, prevent or reduce pin leakage, and enhance timing margins. This can lead to package 103 having improved performance, a relatively small form factor (e.g., smaller size), a cost effective stacked-die structure, and other improvements and benefits described herein. An example ESD solution for dies 111 and 121 based on the technique described herein is discussed in more detail below with reference to FIG. 3 through FIG. 6.

FIG. 3 shows a combined simulation model 303 including simulation models 311 and 321 for ESD protection circuitries of the dies 111 and 121, respectively, and a simulation model 333 for a combining circuit, according to some embodiments described herein. As shown in FIG. 3, simulation model 311 can include schematic diagram modeling showing connections among circuit elements (including the ESD protection structure) of die 111. For example, simulation model 311 can include circuit modeling of a diode circuitry model 310, a clamp circuitry model 312, and a capacitor circuitry model 314 that can be based on the schematic diagram (FIG. 2) of diode circuitry 210, clamp circuitry 212, and capacitor circuitry 214, respectively.

As shown in FIG. 3, simulation model 321 can include schematic diagram modeling showing connections among circuit elements (including the ESD protection structure) of die 121. For example, simulation model 321 can include circuit modeling of a diode circuitry model 320, a clamp circuitry model 322, a capacitor circuitry model 324, a receiver (Rx) circuit model 326, and a transmitter (Tx) circuit model 328 that can be based on the schematic diagram (FIG. 2) of diode circuitry 220, clamp circuitry 222, capacitor circuitry 224, receiver circuit 226, and transmitter circuit 228, respectively.

For simplicity, details of simulation models 311, 321, and 333 are omitted from FIG. 3. However, one skilled in the art upon reading the techniques described herein will readily recognize that simulation models such as simulation models 311, 321, and 333 can be generated (e.g., using simulation software) with details based the schematic diagram of dies 111 and 121 shown in FIG. 2.

Circuitry in each of dies 111 and 121 (FIG. 1 and FIG. 2) may be formed from different technology nodes (e.g., different processes). Thus, simulation models 311 and 321 for dies 111 and 121, respectively, may include circuitry models from different technology nodes. Alternatively, circuitry in each of dies 111 and 121 (FIG. 1 and FIG. 2) may be formed from the same technology node (e.g., same process). Thus, simulation models 311 and 321 for dies 111 and 121, respectively, may include circuitry models from the same technology node.

As shown in FIG. 3, simulation model 333 can represent a model of a resistor R having a resistor terminal coupled to terminal 146c1 (on die 111 side) and a resistor terminal coupled to terminal 146c2 (on die 121 side). Terminal 146c1 can be part of the ESD protection structure of die 111. Terminal 146c2 can be part of the ESD protection structure of die 121. Resistor R may present a combining (e.g., stitching) element to combine (e.g., stitch) simulation models 311 and 321 to each other. Resistor R may not exist in an actual structure of package 103 (FIG. 1). Thus, the resistance value of resistor R can be set to a relatively small value (e.g., 0.001 ohm) for purposes of combining simulation models 311 and 321 to each other. As mentioned here, a combining circuit (e.g., resistor R) may not be included in actual circuitry of dies 111 and 121. However, including the model of the combining circuit (e.g., model 333) in the simulation models for dies 111 and 121 can allow simulation of effective electrical response of the combined simulation models (e.g., simulation models 311 and 321) of dies 111 and 121. This combined simulation can provide a simulation result that can include an optimized solution for the ESD protection structure for each of dies 111 and 121.

FIG. 4 shows a combined simulation file 403 based on simulation models 311, 321, and 333 of FIG. 3, according to some embodiments described herein. As shown in FIG. 4, combined simulation file 403 can include a simulation file 411, a simulation file 421, and a combined simulation file 433. Simulation file 411 in FIG. 4 can include a simulation file (e.g., simulation description) for an ESD protection structure of die 111 that can be generated based on simulation model 311 of FIG. 3. Simulation file 421 can include a simulation file (e.g., simulation description) for an ESD protection structure of die 121 that can be generated based on simulation model 321 of FIG. 3. Simulation file 433 can include a simulation file (e.g., simulation description) for the combining circuit model 333 of FIG. 3. For example, simulation file 433 can include a description of resistor R (which is included in combining circuit model 333) having a value of 0.001 ohm coupled between nodes 146c1 and 146c2 of the ESD protection structure of die 111. Thus, combined simulation file 403 can include a description of an ESD path that passes through at least a portion of the ESD protection structure of die 111, through a model of a combining element, and through at least a portion of the ESD protection structure of die 121.

Thus, as described above, simulation file 411 can include a description (e.g., a simulation description) of the circuit elements of simulation model 311 (FIG. 3). Simulation file 421 can include a description (e.g., a simulation description) of the circuit elements of simulation model 321 (FIG. 3). Simulation file 433 can include description (e.g., simulation description) of the circuit elements of simulation model 333. The description in each of simulation files 411, 421, and 433 can be generated based on a particular simulation software. For example, the description in each of simulation files 411, 421, and 433 can include a netlist (e.g., SPICE netlist) or other types of software simulation description. Thus, in this example, combined simulation file 403 can include a netlist (e.g., SPICE netlist) of an ESD path that include a combination at least a portion of the ESD protection structure of die 111, at least a portion of the ESD protection structure of die 121, and a combining circuit that combines the portion of the ESD protection structure of die 111 and the portion of the ESD protection structure of die 121.

For simplicity, details of simulation files 411, 421, and 433 are omitted from FIG. 4. However, one skilled in the art will readily recognize that simulation files such as simulation files 411, 421, and 433 can be generated (e.g., generated as a netlist) based on simulator models 311, 321, and 333 (FIG. 3) to generate combined simulation file 403.

As mentioned above, circuitry in each of dies 111 and 121 (FIG. 1 and FIG. 2) may be formed from different technology nodes (e.g., different processes). Thus, simulation files 411 and 421 may include simulation information (e.g., process parameters for ESD structure of dies 111 and 121) from different technology nodes. Alternatively, circuitry in each of dies 111 and 121 (FIG. 1 and FIG. 2) may be formed from the same technology node (e.g., same process). Thus, simulation files 411 and 421 may include simulation information (e.g., process parameters for ESD structure of dies 111 and 121) from the same technology node.

The techniques described herein can include executing combined simulation file 433 (FIG. 4) to generate a simulation result. For example, combined simulation file 403 can be executed using a simulation software (e.g., using a SPICE simulator or other types of simulators). Based on the simulation result of the described techniques, ESD protection structure (e.g., actual diode circuitry and actual clamp circuitry) of each of dies 111 and 121 can be configured (e.g., formed). As mentioned above, an optimal ESD protection structure for each of dies 111 and 121 can be achieved based on the techniques described herein.

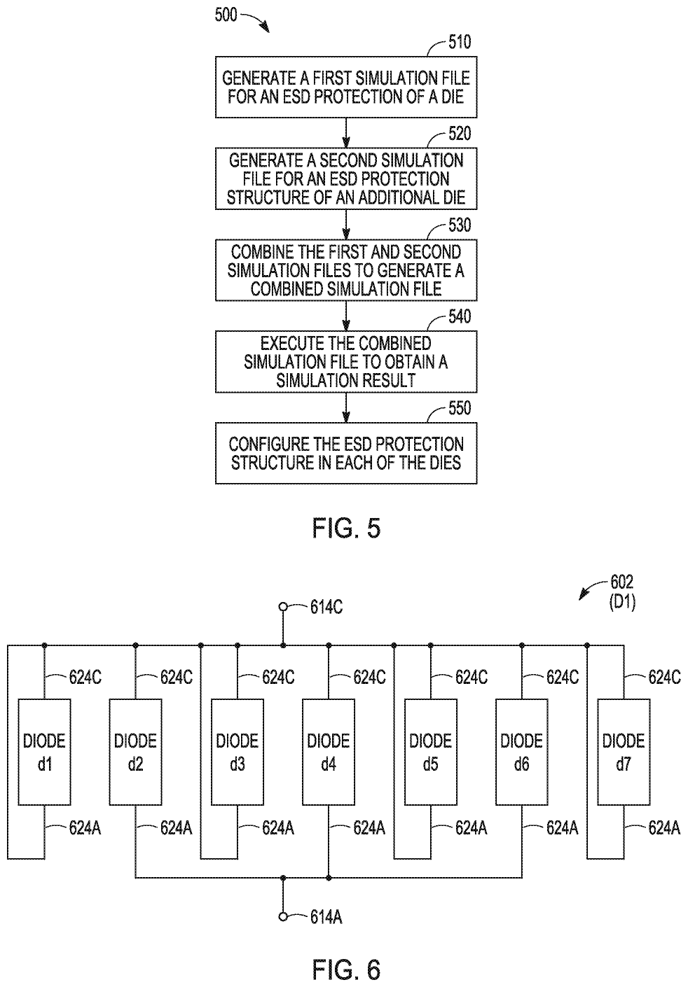

FIG. 5 is a flowchart showing a method 500 for simulating an ESD protection structure of a stacked-die structure, according to some embodiments described herein. The stacked-die structure in method 500 can include the stacked-die structure of package 103 of FIG. 1. Thus, method 500 may be used for die 111 in FIG. 2 (and its corresponding simulation model 311 in FIG. 4) and die 121 in FIG. 2 and (and its corresponding simulation model 321 in FIG. 5). At least a portion of method 500 may be performed using software (e.g., simulation software) on a machine, for example, a computer.

As shown in FIG. 5, activity 510 of method 500 can include generating a first simulation file for an ESD protection structure of a die (e.g., die 111). The first simulation file in activity 510 can include a description of the circuit elements of a simulation model for the ESD protection structure of the die. For example, the first simulation file in activity 510 can include a netlist (e.g., SPICE netlist) or other types of software simulation description. The first simulation file in activity 510 can include simulation file 411 (FIG. 4) based on simulation model 311 (FIG. 3) for the ESD protection structure of die 111.

Activity 520 of method 500 can include generating a second simulation file for an ESD protection structure of an additional die (e.g., die 121). The second simulation file in activity 520 can include a description of the circuit elements of an additional simulation model for the ESD protection structure of the additional die. For example, the second simulation file in activity 510 can include a netlist (e.g., SPICE netlist) or other types of software simulation description. The second simulation file in activity 520 can include simulation file 421 (FIG. 4) based on simulation model 321 (FIG. 3) for the ESD protection structure of die 121.

Activity 530 of method 500 can include combining the first and second simulation files to generate a combined simulation file. Combining the first simulation file with the second simulation file can include adding an additional simulation file to the first and second simulation files. The additional simulation file in activity 530 can combine (e.g., stitch) the first simulation file to the second simulation file. Thus, the combined simulation file in activity 530 can include a combination of the first simulation file, the second simulation file, and the additional simulation file (which combines the first and second simulation files). The additional simulation file can include simulation file 433 of FIG. 4. The combined simulation file in activity 530 can include combined simulation file 403 (FIG. 4) that includes a combination of simulation file 411, simulation file 421, and the simulation file 433.

Activity 540 of method 500 can include executing (e.g., simulating) the combined simulation file to obtain a simulation result. Executing the combined simulation file in activity 540 can be performed until an optimal result (e.g., a desired result) for configuring the ESD protection structure of the dies is achieved. For example, each of the dies (e.g., dies 111 and 112) in method 500 can include respective diode circuitry (diode circuitry 210 or 220 in FIG. 2) that have programmable structures (e.g., programmable connections). The programmable structures can be configured such that different numbers of effective diodes (functional diodes) can be selected (e.g., adjusted) during simulation (e.g., selected during different iterations of the simulation). The combined simulation file in activity 540 in FIG. 5 can be executed (e.g., simulated) until a number (e.g., an optimal number) of diodes in the ESD protection structure in each of the dies (e.g., dies 111 and 121) passes an electrical stress limit (e.g., predetermined electrical stress limit). For example, executing (e.g., simulating) the combined simulation file in activity 540 can include adjusting the number of diodes in each of the dies, such that the combination of diodes in the dies passes ESD rules and limits (e.g., current density and voltages) observed at other circuit elements (e.g., diffusion areas in drivers in the receiver circuits and transmitter circuits) that are coupled to the ESD protection structure in each of the dies.

Activity 550 of method 500 can include configuring the ESD protection structure (actual ESD protection structure) in each of the dies (e.g., die 111 and 121) based on the simulation result obtained in activity 540. For example, configuring ESD protection structure in activity 550 can include at least one of selecting the number of diodes in ESD protection structures of the dies and selecting the number clamp circuits in the ESD protection structures of the dies. As described herein, configuring the ESD protection structure (e.g., selecting the number of diodes) of the dies can based on method 500 can allow the ESD protection structure of each of the dies to achieve optimal ESD protection.

As described above, method 500 can include activities 510, 520, 530, 540, and 550. However, method 500 can include fewer or more activities than the activities shown in FIG. 5.

FIG. 6 shows a schematic diagram of a diode circuit 602 having diodes (e.g., ESD diodes) d1 through d7 and programmable connections, according to some embodiments described herein. FIG. 6 shows diode circuit 602 having seven diodes d1 through d7 as an example. The number of diodes in diode circuit 602 can vary. FIG. 6 shows example connections in diode circuit 602, such that three diodes (d2, d4, and d6) out of seven diodes (d1 through d7) are coupled in parallel between a node (e.g., anode) 614A and a node (e.g., cathode) 614C. Thus, the effective number of diodes (e.g., functional diodes) in diode circuit 602 is three. The number of effective diodes of diode circuit 602 can be formed by configuring (e.g., programming) connections (e.g., conductive paths) between diodes d1 through d7 and nodes 614A and 614C. Configuring the connections in diode circuit 602 can be based on a simulation result obtained from a simulation of a combined simulation file described above with reference to FIG. 5.

Configuring connections in diode circuit 602 can include forming or not forming a connection (e.g., a conductive path (e.g., a conductive via)) between a node (e.g., anode or cathode) of each of diodes d1 through d7 and node 614C (or alternative node 614A) of diode circuit 602. The number of effective diodes (among diodes d1 through d7) coupled in parallel between nodes 614A and 614C can depend on the presence or absence of a connection between node 614C and node 624C of each of diodes d1 through d7.

In the example of FIG. 6, each of diodes d1 through d7 can include a node (e.g., an anode) 624A coupled to node 614A. Each of diodes d1 through d7 can include a node (e.g., a cathode) 624C that can be selectively coupled to node 614C. FIG. 6 shows an example where a connection between node 614A and node 624A of each of diodes d2, d4, and d6 is present, and a connection between node 614A and node 624A of each of diodes d1, d3, d5, and d7 is absent. In this example, nodes 624A and 624C of each of diodes d1, d3, d5, and d7 can be shorted to each other. Thus, in this example, diodes d1, d3, d5, and d7 are non-functional in diode circuit 602. In the example of diode circuit 602 of FIG. 6, current can flow between nodes 614A and 614C through diodes d2, d4, and d6. For example, ESD current from an ESD event can flow between node 614A and 614C through diodes d2, d4, and d6.

FIG. 6 shows label “D1” to indicate that diode circuit 602 can be used as diode circuit D1 of FIG. 2. Nodes 614A and 614C of diode circuit 602 can correspond to the anode and cathode nodes, respectively, of diode circuit D1. Thus, in this example, diode circuit D1 can include diodes d2, d4, and d6 coupled in parallel between nodes 614A and 614C, which can correspond to nodes 210.1 and 210.2, respectively, of diode circuitry 210 of FIG. 2.

Each of other diode circuits D2 through D8 of FIG. 2 can have the structure of diode circuit 602. Thus, other diode circuits D2 through D8 of FIG. 2 can have diodes coupled in parallel with each other between the anode and cathode nodes of the respective diode circuit. For example, diode circuit D2 of FIG. 2 can include multiple diodes (which are different from the multiple diodes of diode circuit D1) coupled in parallel between nodes 210.3 and 210.1 of diode circuitry 210 of FIG. 2. In another example, diode circuit D5 of FIG. 2 can include multiple diodes coupled in parallel between nodes 220.3 and 220.1, and diode circuit D7 of FIG. 2 can include multiple diodes (which are different from the multiple diodes of diode circuit D5) coupled in parallel between nodes 220.3 and 220.1. In another example, diode circuit D6 of FIG. 2 can include multiple diodes coupled in parallel between nodes 220.1 and 220.2, and diode circuit D8 of FIG. 2 can include multiple diodes (which are different from the multiple diodes of diode circuit D6) coupled in parallel between nodes 220.1 and 220.2.

As described above, each of diode circuits D1 through D8 of FIG. 2 can have the structure of diode circuit 602. However, the number of effective diodes (e.g., functional diodes coupled in parallel between the anode and cathode nodes of the respective diode circuit) can be the same or can be different from one diode circuit to another. For example, the number of effective diodes of diode circuit D1 can be different from the number of effective diodes of diode circuit D2 and different from the number of effective diodes of each of other diodes circuits (e.g., diode circuits D3 through D8). In another example, the number of effective diodes of diode circuit D5 can be different from the number of effective diodes of diode circuit D6. Thus, in dies 111 and 121, two or more diode circuits (among diode circuits D1 through D8) can have the same number of effective diodes or a different number of effective diodes coupled in parallel between the anode and cathode of the respective diode circuit. The number of effective diodes in each of diode circuits D1 through D8 of package 103 (FIG. 1 and FIG. 2) can be based on the simulation result (that provides an optimal number of diodes for each of diode circuits D1 through D8) obtained from simulation of a combined model of the ESD protection structure of die 11l and the ESD protection structure of die 121. The combined model described herein can includes at least one of combined simulation model 303 and combine simulation file 403 as described above with reference to FIG. 2 through FIG. 5.

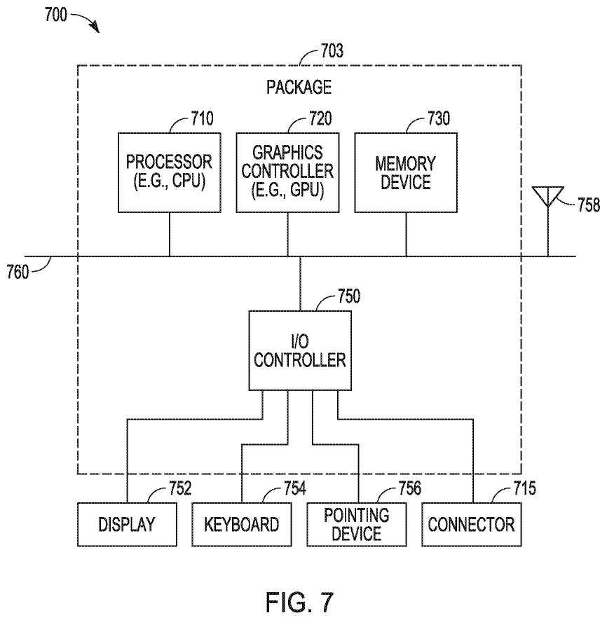

FIG. 7 shows an apparatus in the form of a system (e.g., electronic system) 700, according to some embodiments described herein. System 700 can include or be included in a cellular phone, a computer (e.g., desktop or notebook computer), a tablet, or other electronic devices or systems. As shown in FIG. 7, system 700 can include a package 703, which can include a processor 710, a graphics controller 720, a memory 730, and an I/O controller 750. System 700 can also include a display 752, a keyboard 754, a pointing device 756, at least one antenna 758, a connector 715, and a bus 760.

Package 703 can include package 103 of FIG. 1. Thus, structure of package 703 can include the structure of package 103. Thus, package 703 can include multiple dies and the ESD protection structure described above with reference to FIG. 1 through FIG. 6. For example, package 703 can include multiple dies arranged in stacked-die structure (one die over another). In this example, processor 710, a graphics controller 720, a memory 730, and an I/O controller 750 can be included in the dies of the stacked-die structure. For example, processor 710, graphic controller 720, or both can be included in a die, memory device 730 can included in another die, and I/O controller 750 can be included in a die different from the die of memory device 730. FIG. 7 shows an example where processor 710, graphics controller 720, memory 730, and I/O controller 750 are included in package 703. However, one or more of processor 710, graphics controller 720, memory 730, and I/O controller 750 can be located outside package 703 (e.g., located on a base (e.g., a PCB) such as base 101 of FIG. 1).

In system 700, processor 710 can include a general-purpose processor (or alternatively an application specific integrated circuit (ASIC)) that can include a CPU. Graphics controller 720 can include a GPU. Memory device 730 can include a DRAM device, a static random access memory (SRAM) device, a flash memory device, a phase change memory, or a combination of these memory devices, or other types of memory.

I/O controller 750 can include a communication module for wired or wireless communication (e.g., communication through one or more antenna 758). Such wireless communication may include communication in accordance with WiFi communication technique, Long Term Evolution Advanced (LTE-A) communication technique, or other communication techniques. I/O controller 750 can also include a module to allow system 700 to communicate with other devices or systems in accordance with one or more standards or specifications (e.g., I/O standards or specifications), including Universal Serial Bus (USB), DisplayPort (DP), High-Definition Multimedia Interface (HDMI), Thunderbolt, Peripheral Component Interconnect Express (PCIe), Ethernet, and other specifications.

Display 752 can include a liquid crystal display (LCD), a touchscreen (e.g., capacitive or resistive touchscreen), or another type of display. Pointing device 756 can include a mouse, a stylus, or another type of pointing device.

Connector 715 can be arranged (e.g., can include terminals, such as pins) to allow system 700 to be coupled to an external device (or system). This may allow system 700 to communicate (e.g., exchange information) with such a device (or system) through connector 715. Connector 715 and at least a portion of bus 760 can include conductive lines that conform with at least one of USB, DP, HDMI, Thunderbolt, PCIe, Ethernet, and other specifications.

The illustrations of apparatus (e.g., apparatus 100 and system 700) and methods (e.g., method 500) described above with reference to FIG. 1 through FIG. 6 are intended to provide a general understanding of the structure of various embodiments and are not intended to provide a complete description of all the elements and features of apparatuses that might make use of the structures described herein. Further, although diodes (e.g., D1 through D8 in FIG. 2) are used as ESD circuit elements in the described ESD protection structure, other circuit elements may be used. For example, silicon-controlled rectifiers (SCRs) may also be used in the described ESD protection structure.

The apparatus and methods described herein may include or be included in electronic circuitry, such as high-speed computers, communication and signal processing circuitry, single or multi-processor modules, single or multiple embedded processors, multi-core processors, message information switches, and application-specific modules including multilayer, multi-chip modules. Such apparatuses may further be included as sub-components within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 5) players), vehicles, medical devices (e.g., heart monitor, blood pressure monitor, etc.), set top boxes, and others.

### Additional Notes and Examples

Example 1 includes subject matter (such as a device, an electronic apparatus (e.g., circuit, electronic system, or both), or a machine) including a conductive connection, a first die including a first electrode static discharge (ESD) protection structure, the first ESD protection structure including a first number of circuit elements coupled to the conductive connection, and a second die arranged in a stack with the first die, the second die including a second ESD protection structure, the second ESD protection structure including a second number of circuit elements coupled to the first number of circuit elements, wherein the first number of circuit elements and the second number circuit elements are based on a combined model of the first and second ESD protection structures.

In Example 2, the subject matter of Example 1 may optionally include, wherein the first number of circuit elements includes a first number of diodes, and the second number of circuit elements includes a second number of diodes, and the first number of diodes and the second number of diodes are based on the combined model of the first and second ESD protection structures.

In Example 3, the subject matter of Example 2 may optionally include, wherein the first number of diodes includes first diodes coupled in parallel between a first node and a second node, and first additional diodes coupled in parallel between the second and a third node, and the second number of diodes includes second diodes coupled in parallel between a fourth node and a fifth node, and second additional diodes coupled in parallel between the fifth node and a sixth node.

In Example 4, the subject matter of Example 3 may optionally include, wherein the first number of diodes is included in a first diode circuitry, and the first diode circuitry includes a diode electrically unconnected to one of the first, second, and third nodes, and the second number of diodes is included in a second diode circuitry, and the first diode circuitry includes a diode electrically unconnected to one of the fourth, fifth, and sixth nodes.

In Example 5, the subject matter of Example 3 may optionally include, wherein the first number of diodes is different from the second number of diodes

In Example 6, the subject matter of Example 1 may optionally include, wherein the combined model includes a simulation file for an ESD path that passes through at least a portion of the ESD protection structure of the first die and at least a portion of the ESD protection structure of the second die.

In Example 7, the subject matter of Example 1 may optionally include, wherein the conductive connection includes a controlled collapse chip connection (C4).

In Example 8, the subject matter of Example 7 may optionally include, wherein the first die is coupled to the second die through a solder connection located between the first die and the second die.

In Example 9, the subject matter of Example 1 may optionally include, wherein the first die includes circuitry formed based on a first technology node, and the second die includes circuitry formed based on a second technology node.

Example 10 includes subject matter (such as a device, an electronic apparatus (e.g., circuit, electronic system, or both), or a machine) including a substrate, a first device coupled to the substrate through first conductive connections, a second device coupled to the first device through second conductive connections, and a memory device arrange in a stack with the first and second devices, such that the first and second devices are between the memory device and the substrate, wherein the first device includes a first die, the first die including a first electrode static discharge (ESD) protection structure, the first ESD protection structure including a first diode circuitry coupled to the conductive connection, the first diode circuitry including a first number of diodes, and the second device includes a second die, the second die including a second ESD protection structure, the second ESD protection structure including a second diode circuitry coupled to the first diode circuitry, the second diode circuitry including a second number of diodes, wherein the first number of diodes and the second number of diodes are based on a combined model of the first and second ESD protection structures.

In Example 11, the subject matter of Example 10 may optionally include, wherein the first die includes a through silicon via (TSV), and the TSV includes a first end coupled to the substrate and a second end coupled to the second die.

In Example 12, the subject matter of Example 10 may optionally include, wherein the second device includes at least one of a central processing unit and a graphics processing unit.

In Example 13, the subject matter of Example 12 may optionally include, wherein the first device includes a cache memory circuit.

In Example 14, the subject matter of Example 10 may optionally include, wherein the memory device is electrically coupled to the substrate through conductive wires.

In Example 15, the subject matter of Example 10 may optionally include, further comprising a connector coupled to the processor, the connector conforming with one of Universal Serial Bus (USB), High-Definition Multimedia Interface (HDMI), Thunderbolt, Peripheral Component Interconnect Express (PCIe), and Ethernet specifications.

In Example 16, the subject matter of Example 10 may optionally include, further comprising an antenna coupled to the substrate.

In Example 17, the subject matter of Example 10 may optionally include, further comprising a printed circuit board coupled to the substrate.

In Example 18, the subject matter of Example 10 may optionally include, wherein the substrate includes an organic substrate.

Example 19 includes subject matter (such as a method of operating a device, an electronic apparatus (e.g., circuit, electronic system, or both), or a machine) including generating a first simulation file for a first electrode static discharge (ESD) protection structure of a first die, generating a second simulation file for a second ESD protection structure of a second die, combining the first and second simulation files to generate a combined simulation file, such that the combined simulation file includes a description of an ESD path that passes through at least a portion of the first protection circuitry and at least a portion of the second protection circuitry, and executing the combined simulation file to obtain a simulation result.

In Example 20, the subject matter of Example 19 may optionally include, wherein combining the first and second simulation files includes adding a description of a circuit element in the combined simulation file to form a conductive path between a terminal included in the first ESD protection structure and a terminal included in the second ESD protection structure.

In Example 21, the subject matter of Example 20 may optionally include, wherein the circuit element includes a resistor having a first resistor terminal coupled to the terminal included in the first ESD protection structure, and a second resistor terminal coupled to the terminal included in the second ESD protection structure.

In Example 22, the subject matter of Example 19 may optionally include, wherein each of the first and second simulation files includes a netlist.

In Example 23, the subject matter of Example 19 may optionally include, wherein executing the combined simulation file to obtain the simulation result is performed until a diode circuitry on at least one the first die and the second die reaches an electrical stress limit.

In Example 24, the subject matter of Example 19 may optionally include, wherein executing the combined simulation file to obtain the simulation result is performed until a first diode circuitry on the first die reaches a first electrical stress limit, and until a second diode circuitry of at least one of the first second ESD protection structures reaches a second electrical stress limit.

In Example 25, the subject matter of Example 24 may optionally include, further comprising selecting a first number of diodes in the first diode circuitry to be diodes for the first ESD protection structure of the first die, and selecting a second number of diodes in the second diode circuitry to be diodes for the second ESD protection structure of the second die.

The subject matter of Example 1 through Example 25 may be combined in any combination.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments to enable those skilled in the art to practice the embodiments of the invention. Other embodiments may incorporate structural, logical, electrical, process, and other changes. Examples merely typify possible variations. Portions and features of some embodiments may be included in, or substituted for, those of other embodiments. Many other embodiments will be apparent to those of skill in the art upon reading and understanding the above description. Therefore, the scope of various embodiments is determined by the appended claims, along with the full range of equivalents to which such claims are entitled.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprising:
a conductive connection;
a first die including a first electrode static discharge (ESD) protection structure, the first ESD protection structure including a first number of circuit elements coupled to the conductive connection; and
a second die arranged in a stack with the first die, the second die including a second ESD protection structure, the second ESD protection structure including a second number of circuit elements coupled to the first number of circuit elements, wherein the first number of circuit elements and the second number circuit elements are based on a combined model of the first and second ESD protection structures.

2. The apparatus of claim 1, wherein:
the first number of circuit elements includes a first number of diodes; and
the second number of circuit elements includes a second number of diodes, and the first number of diodes and the second number of diodes are based on the combined model of the first and second ESD protection structures.

3. The apparatus of claim 2, wherein:
the first number of diodes includes first diodes coupled in parallel between a first node and a second node, and first additional diodes coupled in parallel between the second and a third node; and
the second number of diodes includes second diodes coupled in parallel between a fourth node and a fifth node, and second additional diodes coupled in parallel between the fifth node and a sixth node.

4. The apparatus of claim 3, wherein:
the first number of diodes is included in a first diode circuitry, and the first diode circuitry includes a diode electrically unconnected to one of the first, second, and third nodes; and
the second number of diodes is included in a second diode circuitry, and the first diode circuitry includes a diode electrically unconnected to one of the fourth, fifth, and sixth nodes.

5. The apparatus of claim 3, wherein the first number of diodes is different from the second number of diodes.

6. The apparatus of claim 1, wherein the combined model includes a simulation file for an ESD path that passes through at least a portion of the ESD protection structure of the first die and at least a portion of the ESD protection structure of the second die.

7. The apparatus of claim 1, wherein the conductive connection includes a controlled collapse chip connection (C4).

8. The apparatus of claim 7, wherein the first die is coupled to the second die through a solder connection located between the first die and the second die.

9. The apparatus of claim 1, wherein the first die includes circuitry formed based on a first technology node, and the second die includes circuitry formed based on a second technology node.

10. An apparatus comprising:
a substrate;
a first device coupled to the substrate through first conductive connections;
a second device coupled to the first device through second conductive connections; and
a memory device arrange in a stack with the first and second devices, such that the first and second devices are between the memory device and the substrate, wherein:
the first device includes a first die, the first die including a first electrode static discharge (ESD) protection structure, the first ESD protection structure including a first diode circuitry coupled to the conductive connection, the first diode circuitry including a first number of diodes; and
the second device includes a second die, the second die including a second ESD protection structure, the second ESD protection structure including a second diode circuitry coupled to the first diode circuitry, the second diode circuitry including a second number of diodes, wherein the first number of diodes and the second number of diodes are based on a combined model of the first and second ESD protection structures.

11. The apparatus of claim 10, wherein the first die includes a through silicon via (TSV), and the TSV includes a first end coupled to the substrate and a second end coupled to the second die.

12. The apparatus of claim 10, wherein the second device includes at least one of a central processing unit and a graphics processing unit.

13. The apparatus of claim 12, wherein the first device includes a cache memory circuit.

14. The apparatus of claim 10, wherein the memory device is electrically coupled to the substrate through conductive wires.

15. The apparatus of claim 10, further comprising a connector coupled to the processor, the connector conforming with one of Universal Serial Bus (USB), High-Definition Multimedia Interface (HDMI), Thunderbolt, Peripheral Component Interconnect Express (PCIe), and Ethernet specifications.

16. The apparatus of claim 10, further comprising an antenna coupled to the substrate.

17. The apparatus of claim 10, further comprising a printed circuit board coupled to the substrate.

18. The apparatus of claim 10, wherein the substrate includes an organic substrate.

19. A method comprising:
generating a first simulation file for a first electrode static discharge (ESD) protection structure of a first die;
generating a second simulation file for a second ESD protection structure of a second die;
combining the first and second simulation files to generate a combined simulation file, such that the combined simulation file includes a description of an ESD path that passes through at least a portion of the first protection circuitry and at least a portion of the second protection circuitry; and
executing the combined simulation file to obtain a simulation result.

20. The method of claim 19, wherein combining the first and second simulation files includes adding a description of a circuit element in the combined simulation file to form a conductive path between a terminal included in the first ESD protection structure and a terminal included in the second ESD protection structure.

21. The method of claim 20, wherein the circuit element includes a resistor having a first resistor terminal coupled to the terminal included in the first ESD protection structure, and a second resistor terminal coupled to the terminal included in the second ESD protection structure.

22. The method of claim 19, wherein each of the first and second simulation files includes a netlist.

23. The method of claim 19, wherein executing the combined simulation file to obtain the simulation result is performed until a diode circuitry on at least one the first die and the second die reaches an electrical stress limit.

24. The method of claim 19, wherein executing the combined simulation file to obtain the simulation result is performed until a first diode circuitry on the first die reaches a first electrical stress limit, and until a second diode circuitry on the second die reaches a second electrical stress limit.

25. The method of claim 24, further comprising:
selecting a first number of diodes in the first diode circuitry to be diodes for the first ESD protection structure of the first die; and
selecting a second number of diodes in the second diode circuitry to be diodes for the second ESD protection structure of the second die.
